(19) United States
(12) Patent Application Publication
(10) Pub. No.: US 2017/0012197 A1
(43) Pub. Date: Jan. 12, 2017

(54) Variable-Resisance Element and Production Method Therefor

(71) Applicant: ULVAC, INC., Kanagawa (JP)

(72) Inventors: Natsuki Fukuda, Kanagawa (JP); Kazunori Fukuju, Kanagawa (JP); Yuusuke Miyaguchi, Kanagawa (JP); Yutaka Nishioka, Kanagawa (JP); Koukou Suu, Kanagawa (JP)

(21) Appl. No.: 15/120,666

(22) PCT Filed: Feb. 13, 2015
(86) PCT No.: PCT/JP2015/000680

§ 371 Date: Aug. 22, 2016

(30) Foreign Application Priority Data
Feb. 24, 2014 (JP) 2014-032520

(51) Int. Cl. H01L 45/00

(52) U.S. Cl. CPC H01L 45/146; H01L 45/08; H01L 45/1253; H01L 45/1608

(57) ABSTRACT

To provide a low-cost variable-resistance element and a production method therefor. According to an embodiment of the present invention, there is provided a variable-resistance element 1 including a lower electrode layer 3, an upper electrode layer 5, and an oxide semiconductor layer 4. The upper electrode layer 5 is formed of a carbon material. The oxide semiconductor layer 4 includes a first metal oxide layer 41 and a second metal oxide layer 42. The first metal oxide layer 41 is formed between the lower electrode layer 3 and the upper electrode layer 5 and includes a first resistivity. The second metal oxide layer 42 is formed between the first metal oxide layer 41 and the upper electrode layer 5 and includes a second resistivity different from the first resistivity.

### TECHNICAL FIELD

The present invention relates to a variable-resistance element used as a nonvolatile memory and the like and a production method therefor.

### BACKGROUND ART

Semiconductor memories include a volatile memory such as a DRAM (Dynamic Random Access Memory) and a nonvolatile memory such as a flash memory. A NAND-type flash memory is mainly used as the nonvolatile memory, but since the NAND-type flash memory is the limit of miniaturization under the design rule of 20 nm and subsequent generations, a ReRAM (Resistance RAM) is attracting attention as a device that can be additionally miniaturized.

The ReRAM of the related art has a structure in which a metal oxide layer having a desired resistance value is sandwiched between upper and lower platinum (Pt) electrode layers. By applying a voltage onto the upper electrode layer and changing a resistance of the metal oxide layer, memory switching is performed (see Patent Document 1 below).

Patent Document 1: Japanese Patent Application Laid-open No. 2013-207130

### SUMMARY OF INVENTION

### Problem to be Solved by the Invention

However, since Pt used as the material of the electrode layers is expensive metal, there is a need to develop a non-noble metal electrode material for lowering costs of the variable-resistance element and raising productivity.

In view of the circumstances as described above, the present invention aims at providing a low-cost variable-resistance element and a production method therefor.

### Means for Solving the Problem

To attain the object described above, according to an embodiment of the present invention, there is provided a variable-resistance element including a first electrode layer, a second electrode layer, and an oxide semiconductor layer.

The second electrode layer is formed of a carbon material.

The oxide semiconductor layer includes a first metal oxide layer and a second metal oxide layer. The first metal oxide layer is formed between the first electrode layer and the second electrode layer and includes a first resistivity. The second metal oxide layer is formed between the first metal oxide layer and the second electrode layer and includes a second resistivity different from the first resistivity.

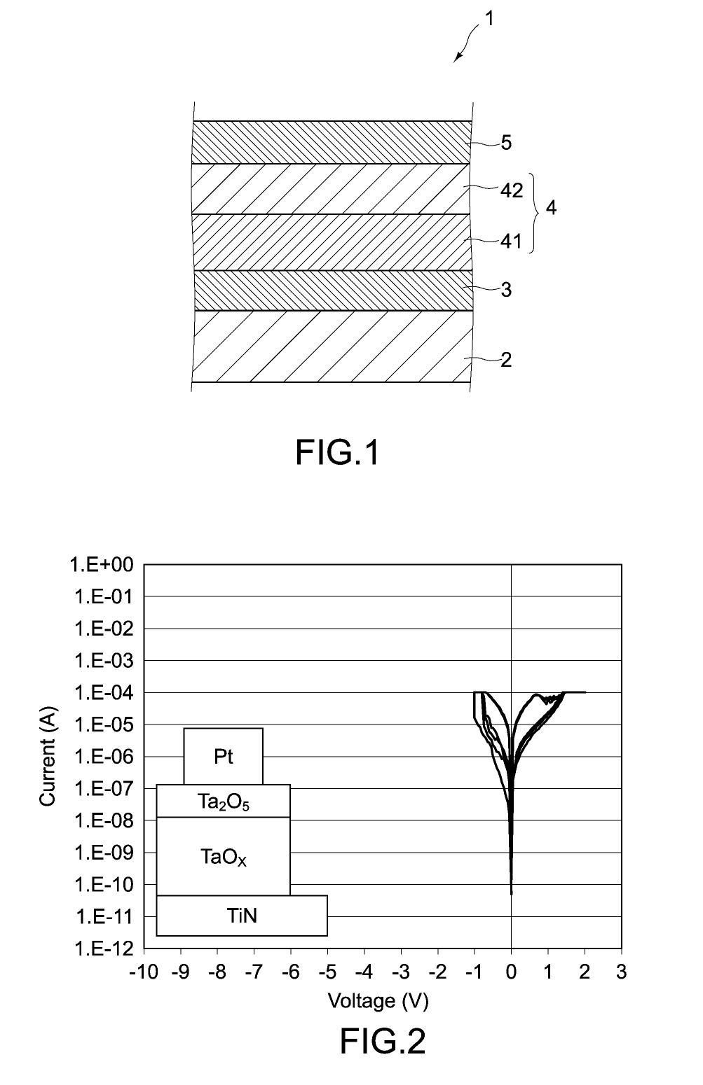

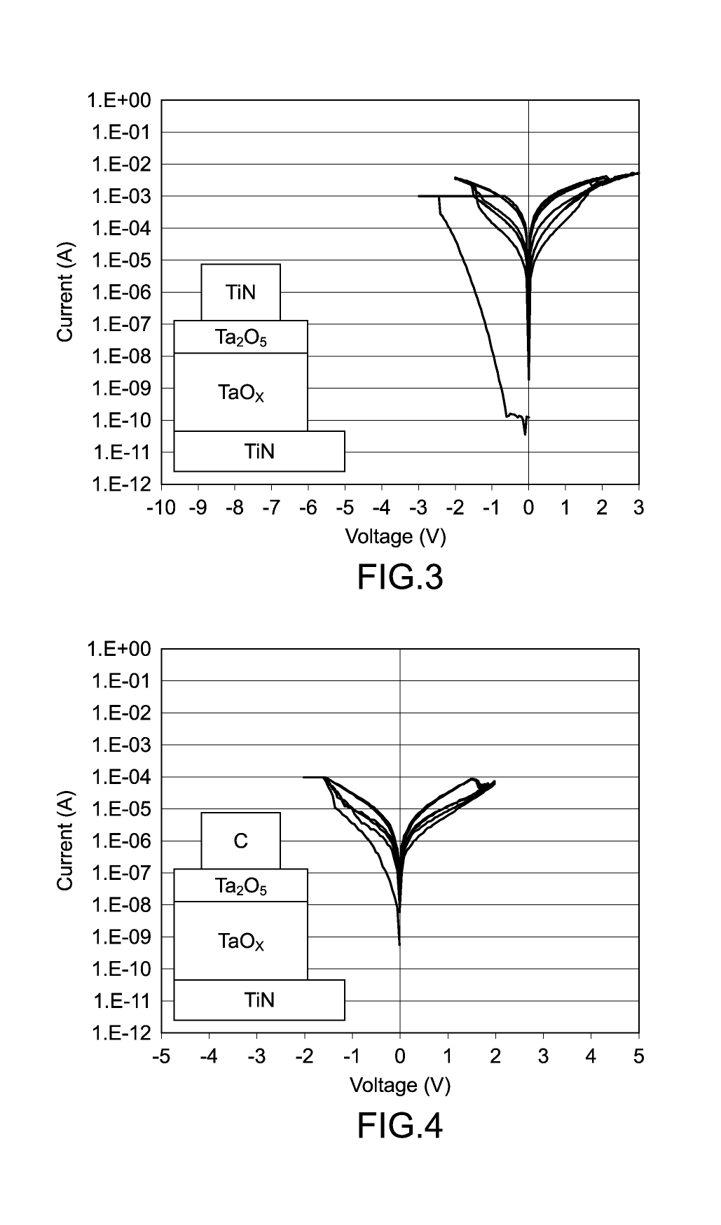

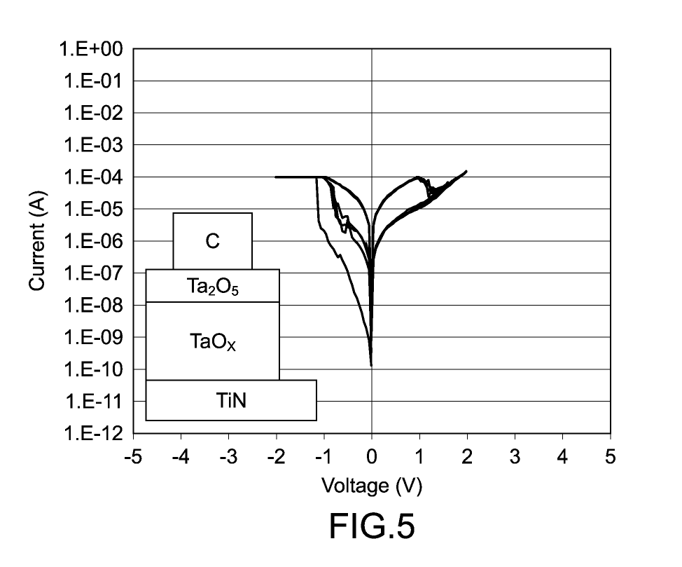

### BRIEF DESCRIPTION OF DRAWINGS

[FIG. 1] A schematic side cross-sectional diagram showing a structure of a variable-resistance element according to an embodiment of the present invention.

[FIG. 2] A diagram showing current-voltage characteristics of a variable-resistance element produced in an experiment.

[FIG. 3] A diagram showing current-voltage characteristics of the variable-resistance element produced in the experiment.

[FIG. 4] A diagram showing current-voltage characteristics of the variable-resistance element according to the embodiment of the present invention.

[FIG. 5] A diagram showing current-voltage characteristics of the variable-resistance element according to the embodiment of the present invention.

### MODE FOR CARRYING OUT THE INVENTION

A variable-resistance element according to an embodiment of the present invention includes a first electrode layer, a second electrode layer, and an oxide semiconductor layer.

The second electrode layer is formed of a carbon material.

The oxide semiconductor layer includes a first metal oxide layer and a second metal oxide layer. The first metal oxide layer is formed between the first electrode layer and the second electrode layer and includes a first resistivity. The second metal oxide layer is formed between the first metal oxide layer and the second electrode layer and includes a second resistivity different from the first resistivity.

In the variable-resistance element, the second electrode layer is formed of a carbon material. Since the carbon material is cheaper than noble metal such as Pt, costs can be cut.

The carbon material may be diamond-like carbon (DLC).

The DLC has a sp³ hybrid trajectory of diamonds and a sp² hybrid trajectory of graphite and includes a non-crystalline (amorphous) structure. The DLC is a carbon material having excellent abrasion resistance, chemical resistance, hygroscopic resistance, oxygen permeability resistance, and the like. With this structure, since the second electrode layer becomes an electrode layer with which it is difficult to transmit and absorb oxygen, it becomes possible to suppress drawing of oxygen in the oxide semiconductor layer and prevent resistance of the oxide semiconductor layer from becoming low. As a result, switching characteristics of the variable-resistance element can be improved.

A density value of the diamond-like carbon may be within a range of 2.3 g/cm³ or more and 2.6 g/cm³ or less.

Since the DLC has a high density within the density range described above and a low resistivity, by using the DLC within the density range described above as the material of the second electrode layer, it becomes possible to obtain an electrode layer with which it is more difficult to absorb oxygen of the oxide semiconductor layer and that has an excellent electrical conductivity.

According to an embodiment of the present invention, there is provided a method of producing a variable-resistance element including forming a first electrode layer on a substrate.

A first metal oxide layer including a first resistivity is formed on the first electrode layer.

A second metal oxide layer including a second resistivity different from the first resistivity is formed on the first metal oxide layer.

A second electrode layer formed of DLC is formed on the second metal oxide layer by RF sputtering or pulse DC sputtering.

By this production method, a variable-resistance element having favorable switching characteristics while requiring lower costs than in a case where noble metal is used for the electrode can be produced.

Hereinafter, an embodiment of the present invention will be described with reference to the drawings.

### First Embodiment

FIG. 1 is a schematic cross-sectional diagram showing a structure of a variable-resistance element according to an embodiment of the present invention. The variable-resistance element 1 of this embodiment includes a substrate 2, a lower electrode layer 3 (first electrode layer), an oxide semiconductor layer 4, and an upper electrode layer 5 (second electrode layer).

A semiconductor substrate such as a silicon wafer is typically used as the substrate 2, but the substrate 2 is not limited thereto, and a ceramic substrate having an insulation property, such as a glass substrate, may also be used.

The oxide semiconductor layer 4 includes a first metal oxide layer 41 and a second metal oxide layer 42. Although the first metal oxide layer 41 and the second metal oxide layer 42 are formed of the same type of materials, they may be formed of different types of materials. One of the first metal oxide layer 41 and the second metal oxide layer 42 is formed of an oxide material close to a stoichiometric composition (hereinafter, also referred to as “stoichiometric composition material”), and the other is formed of an oxide material including a large number of oxygen defects (hereinafter, also referred to as “oxygen defect material”). In this embodiment, the first metal oxide layer 41 is formed of the oxygen defect material, and the second metal oxide layer 42 is formed of the stoichiometric composition material.

The first metal oxide layer 41 is formed on the lower electrode layer 3 and formed of tantalum oxide (TaOₓ) in this embodiment. The tantalum oxide used for the first metal oxide layer 41 has a lower oxidation degree than tantalum oxide forming the second metal oxide layer 42, and a resistivity thereof is, for example, larger than 1 Ω·cm and 1*10⁶ Ω·cm or less.

The material forming the first metal oxide layer 41 is not limited to that described above, and examples thereof include binary or ternary or more oxide materials such as zirconium oxide (ZrOₓ), hafnium oxide (HfOₓ), titanium oxide (TiOₓ), aluminum oxide (AlOₓ), silicon oxide (SiOₓ), iron oxide (FeOₓ), nickel oxide (NiOₓ), cobalt oxide (CoOₓ), manganese oxide (MnOₓ), tin oxide (SnOₓ), zinc oxide (ZnOₓ), vanadium oxide (VOₓ), tungsten oxide (WOₓ), copper oxide (CuOₓ), Pr(Ca, Mn)O₃, LaAlO₃, SrTiO₃, and La(Sr, Mn)O₃.

The second metal oxide layer 42 is formed on the first metal oxide layer 41 and formed of tantalum oxide (Ta₂O₅) in this embodiment. The tantalum oxide used for the second metal oxide layer 42 has a stoichiometric composition or a composition close to the stoichiometric composition and has a resistivity larger than 1*10⁶(1E+06)Ω·cm. The material forming the second metal oxide layer 42 is not limited thereto, and binary or ternary or more oxide materials as those described above are applicable.

The first metal oxide layer 41 and the second metal oxide layer 42 can be formed by a reactive sputtering method with oxygen, for example. In this embodiment, by sputtering a metal (Ta) target in a vacuum chamber into which oxygen is introduced, the metal oxide layers 41 and 42 each formed of tantalum oxide can be successively formed on the substrate 2 (lower electrode layer 3). Oxidation degrees of the metal oxide layers 41 and 42 are controlled by a flow rate (partial pressure) of oxygen introduced into the vacuum chamber.

Since the second metal oxide layer 42 of the variable-resistance element 1 has a higher oxidation degree than the first metal oxide layer 41, the second metal oxide layer 42 has a higher resistivity than the first metal oxide layer 41. Here, when a positive voltage and a negative voltage are respectively applied to the upper electrode layer 5 and the lower electrode layer 3, oxygen ions (O²⁻) in the highly-resistive second metal oxide layer 42 are dispersed in the lowly-resistive first metal oxide layer 41, with the result that the resistance of the second metal oxide layer 42 is lowered (low-resistance state). On the other hand, when a positive voltage and a negative voltage are respectively applied to the lower electrode layer 3 and the upper electrode layer 5, oxygen ions are dispersed from the first metal oxide layer 41 to the second metal oxide layer 42, with the result that the oxidation degree of the second metal oxide layer 42 is raised and the resistance also becomes high (high-resistance state).

As described above, the oxide semiconductor layer 4 reversibly makes switches between the low-resistance state and the high-resistance state by controlling voltages between the lower electrode layer 3 and the upper electrode layer 5. Further, the low-resistance state and the high-resistance state are maintained even when a voltage is not applied. Therefore, the variable-resistance element 1 can be used as a nonvolatile memory element by, for example, writing data in the high-resistance state and reading data in the low-resistance state.

For upper and lower electrode layers of a variable-resistance element of the related art, noble metal such as Pt has been used since it has high corrosion resistance and a favorable conductivity. However, noble metal such as Pt is expensive, and microfabrication such as etching is also difficult, thus not being suited for mass production. Therefore, for lowering costs of the variable-resistance element and raising productivity, there is a need to develop electrode layers formed of a non-noble metal material.

FIG. 2 is an experimental result showing current-voltage characteristics of a variable-resistance element that uses Pt for the upper electrode layer and TiN for the lower electrode layer. In the figure, the abscissa axis represents the voltage, and the ordinate axis represents the current. As shown in FIG. 2, using TiN, that is used as barrier metal and the like, for the lower electrode layer as a typical non-noble metal electrode material, the inventors of the present invention confirmed the switching characteristics of the same level as the Pt lower electrode layer.

On the other hand, FIG. 3 is an experimental result showing current-voltage characteristics of the variable-resistance element that uses TiN for the upper and lower electrode layers. Depositing TiN as the upper electrode layer by a sputtering method, a film having a high insulation property (TaNO film) was formed on an interface between the TiN upper electrode layer and the oxide semiconductor layer by nitrogen plasma. In this case, to use it as the variable-resistance element, element initialization processing called forming that causes a phenomenon similar to an insulation breakdown by applying a voltage equal to or higher than a switching operation voltage onto the oxide semiconductor layer becomes necessary as shown in FIG. 3. It is considered that by generating a current path called filament in the oxide semiconductor layer by forming, a switch operation of the oxide semiconductor layer is caused. However, there is a problem that since the size and position of the filament cannot be controlled appropriately in forming, an operation current cannot be reduced, and an operation current of the element becomes high.

Further, since TiN (specifically, Ti in TiN) is apt to react with oxygen in the oxide semiconductor layer, there is a fear that TiN will draw out oxygen in the oxide semiconductor layer to lower the insulation property of the oxide semiconductor layer and favorable switching of low-voltage low-current drive of the element will not be obtained.

In this regard, the inventors of the present invention have found DLC as a non-noble metal electrode material that is difficult to react with oxygen in the oxide semiconductor layer and does not require nitrogen plasma during deposition.

The DLC is a carbon material having excellent abrasion resistance, chemical resistance, hygroscopic resistance, oxygen permeability resistance, and the like. Due to these properties, the DLC is used as a cutting tool or a coating material for plastic bottles, for example. Furthermore, the DLC has a sp³ hybrid trajectory of carbon constituting diamonds and a sp² hybrid trajectory of carbon constituting graphite and includes an amorphous structure. With this structure, the DLC has a high density and electrical conductivity.

The upper electrode layer 5 is formed of a carbon material. The carbon material used for the upper electrode layer 5 is not particularly limited as long as it has electrical conductivity. For example, graphite, DLC, or the like is used. These carbon materials are cheaper than noble metal such as Pt, and thus costs of the element can be cut.

In this embodiment, the upper electrode layer 5 is formed of the DLC. Accordingly, it becomes difficult for the upper electrode layer 5 to transmit and absorb oxygen in the oxide semiconductor layer 4 (mainly second metal oxide layer 42), and drawing of oxygen from the oxide semiconductor layer 4 is suppressed. As a result, it becomes possible to prevent the resistance of the oxide semiconductor layer 4 from becoming low.

Examples of the method of forming a DLC layer as the upper electrode layer 5 include a sputtering method and a CVD (Chemical Vapor Deposition) method. In this embodiment, the DLC layer is formed on the second metal oxide layer 42 by RF sputtering or pulse DC sputtering. Graphite having a high purity and high density is used as the target in each of the sputtering methods described above.

The density of the DLC layer is controlled based on a temperature (20° C. to 300° C.) and an RF bias (0 W to 300 W), and a value thereof falls within the range of 1.0 g/cm³ or more and 3.0 g/cm³ or less. The value within the range of 1.9 g/cm³ or more and 2.6 g/cm³ or less means that the DLC layer is suited as the electrode due to high oxygen permeability resistance and low resistance. Further, the value within the range of 2.3 g/cm³ or more and 2.6 g/cm³ or less means that the DLC layer is favorable as the electrode due to additionally-high oxygen permeability resistance and additionally-low resistance. The value within the range of 1.0 g/cm³ or more and smaller than 1.9 g/cm³ means that the resistance is low although the oxygen permeability resistance is slightly lowered, and the DLC layer can be used as the electrode. On the other hand, when the value is of a higher density than 2.6 g/cm³, the resistance rises although the oxygen permeability resistance is high, and thus the DLC layer is unsuited to be used as the electrode.

The material forming the lower electrode layer 3 is not particularly limited, and the lower electrode layer 3 may be formed of the same type of material as the upper electrode layer 5 or may be formed of a different type of material. In this embodiment, the lower electrode layer 3 is formed of TiN.

As described above, according to the variable-resistance element 1 of this embodiment, since the upper electrode layer 5 is formed of DLC as a carbon material, costs can be cut more than in the case where the upper electrode layer is formed of noble metal such as Pt. Further, since the DLC is a carbon material having oxygen permeability resistance, it becomes difficult for the upper electrode layer 5 to transmit and absorb oxygen in the oxide semiconductor layer 4, and thus drawing of oxygen from the oxide semiconductor layer 4 is suppressed. As a result, it becomes possible to prevent the resistance of the oxide semiconductor layer 4 from becoming low. Consequently, the switching characteristics of the variable-resistance element can be improved.

Next, a method of producing the variable-resistance element 1 shown in FIG. 1 will be described.

First, the lower electrode layer 3 is formed on the substrate 2. The lower electrode layer 3 can be formed by various deposition methods such as a vacuum deposition method, a sputtering method, a CVD method, and an ALD (Atomic Layer Deposition) method. It is favorable for the lower electrode layer 3 to not have a grain boundary and be flat.

In this embodiment, titanium nitride (TiN) is formed as the lower electrode layer 3 by a reactive sputtering method using a Ti target in a nitrogen and argon atmosphere. The thickness thereof is not particularly limited and is, for example, 50 nm.

Next, the oxide semiconductor layer 4 is formed on the lower electrode layer 3. First, as the first metal oxide layer 41, a tantalum oxide layer having a smaller oxygen amount than a stoichiometric composition is formed by a vacuum deposition method, a sputtering method, a CVD method, an ALD method, or the like. The thickness thereof is not particularly limited and is, for example 20 nm. In this embodiment, the first metal oxide layer 41 is formed by reactive sputtering with oxygen.

Subsequently, the second metal oxide layer 42 is formed on the first metal oxide layer 41. In this embodiment, as the second metal oxide layer 42, a tantalum oxide layer having a stoichiometric composition or an oxygen composition ratio close to the stoichiometric composition is deposited. The thickness thereof is not particularly limited and is, for example, 10 nm. The deposition method is not particularly limited, and the second metal oxide layer 42 is formed by a vacuum deposition method, a sputtering method, a CVD method, or an ALD method, for example. In this embodiment, the second metal oxide layer 42 is formed by a reactive sputtering method with oxygen.

Next, the upper electrode layer 5 is formed on the oxide semiconductor layer 4. In this embodiment, the DLC layer is formed as the upper electrode layer 5 by RF sputtering or pulse DC sputtering.

The conditions for the RF sputtering are not particularly limited, and the RF sputtering can be performed under the following conditions, for example.

Gas (Ar) flow rate: 50 (sccm)

RF power: 2000 (W)

RF frequency: 13.56 (MHz)

Further, the conditions for the pulse DC sputtering are not particularly limited, and the pulse DC sputtering can be performed under the following conditions, for example.

Gas (Ar) flow rate: 50 (sccm)

Pulse DC power: 2000 (W)

Pulse DC frequency: 20 (kHz)

Here, by controlling the deposition temperature of each sputtering method to be within 20° C. to 300° C. and the RF bias to be within 0 W to 300 W, the density value of the DLC layer can be adjusted to fall within the range of 1.9 g/cm³ or more and 2.8 g/cm³ or less. The thickness of the DLC layer is not particularly limited and is, for example, 50 nm.

The variable-resistance element 1 is formed in a predetermined element size. As the patterning of each layer, a lithography and dry etching technique may be used or a lithography and wet etching technique may be used. Alternatively, deposition of each layer may be performed via a resist mask and the like. When using the etching technique, the variable-resistance element 1 may be incorporated in an interlayer insulation film between a lower wiring layer and an upper wiring layer.

According to the production method described above, nitrogen plasma is not used in the deposition of the upper electrode layer 5, and a film having a high insulation property is not formed in the second metal oxide layer 42. Therefore, a voltage required for forming can be lowered or forming becomes unnecessary. Accordingly, it becomes possible to prevent an operation current of the element from rising. Further, since the upper electrode layer 5 is formed of DLC as a carbon material with which it is difficult to transmit and absorb oxygen, drawing of oxygen from the oxide semiconductor layer 4 is suppressed, and the resistance of the oxide semiconductor layer 4 can be prevented from being lowered. Therefore, it becomes possible to produce a variable-resistance element that is lower in costs than a case where noble metal is used for the electrode layer and has favorable switching characteristics.

### EXPERIMENTAL EXAMPLE

4 DLC films having different densities were deposited on a thermally-oxidized-film-attached Si substrate by a sputtering method according to the method of producing a variable-resistance element 1 described above. The deposition was performed by pulse DC sputtering in experimental examples 1 and 2 and by RF sputtering in experimental examples 3 and 4. The thickness of the DLC film was set to be 50 nm, the power frequency in the pulse DC sputtering was set to be 20 kHz, and the power frequency in the RF sputtering was set to be 13.56 MHz. After that, the density (g/cm³) and resistivity ρ (Ω·cm) of the deposited 4 DLC films were measured.

Table 1 is a table that shows the DLC films deposited in the experimental examples and the densities and resistivity thereof. It should be noted that the reference example of Table 1 is a reference value of the DLC film having a density of 2.8 g/cm³.

TABLE 1

| | | Resistivity |
|---|---|---|
| | Density (g/cm³) | (Ω · cm) |
| Experimental example 1 | 1.9 | 0.21 |
| Experimental example 2 | 2.2 | 0.07 |
| Experimental example 3 | 2.4 | 0.055 |
| Experimental example 4 | 2.5 | 0.03 |
| Reference example | 2.8 | 8.00E+06 |

As shown in Table 1, d=1.9 and ρ=0.21 were obtained in Experimental example 1, d=2.2 and ρ=0.07 were obtained in Experimental example 2, and the DLC films deposited by the pulse DC sputtering were of a high density and low resistivity. In addition, d=2.4 and ρ=0.055 were obtained in Experimental example 3, d=2.5 and ρ=0.03 were obtained in Experimental example 4, and the DLC films deposited by the RF sputtering were of a higher density and lower resistivity. On the other hand, the DLC film at d=2.8 in the reference example showed a high resistivity of ρ=8.00E+06.

It should be noted that the density was obtained by an X-ray reflectivity method (XRR). Further, the resistivity was obtained by a product of a sheet resistance value measured by a four-terminal method and a film thickness.

From the results above, when the density value is within the range of 1.9 g/cm³ or more and 2.5 g/cm³ or less, the DLC film has high oxygen permeability resistance and low resistance, so the DLC film is considered to be suited as the electrode of the variable-resistance element. Furthermore, when the density value is within the range of 2.4 g/cm³ or more and 2.5 g/cm³ or less, the DLC film has higher oxygen permeability resistance and lower resistance, so the DLC film is considered to be favorable as the electrode of the variable-resistance element. On the other hand, in the case of a DLC film having a high density of 2.8 g/cm³ or more, the oxygen permeability resistance is high but the resistance rises, so the DLC film is unsuited as the electrode.

FIGS. 4 and 5 are diagrams respectively showing current-voltage characteristics of the variable-resistance elements 1a and 1b obtained by the method of producing a variable-resistance element 1 described above. In the variable-resistance elements 1a and 1b, only the structure of the upper electrode layer 5 differs. Specifically, the variable-resistance element 1a having the current-voltage characteristics shown in FIG. 4 includes a DLC layer that is deposited by the pulse DC sputtering and has a density of 1.9 g/cm³ as the upper electrode layer 5. The variable-resistance element 1b having the current-voltage characteristics shown in FIG. 5 includes a DLC layer that is deposited by the RF sputtering and has a density of 2.4 g/cm³ as the upper electrode layer 5.

As shown in FIGS. 4 and 5, it was found that the variable-resistance elements 1a and 1b have favorable switching characteristics. It can be seen that particularly the variable-resistance element 1b has favorable switching characteristics of low-voltage low-current drive due to a low OFF current and a low drive voltage. From this result, it is considered that the oxygen permeability resistance of the variable-resistance element 1b rises since it includes a DLC layer having a higher density than that of the variable-resistance element 1a, and thus drawing of oxygen in the second metal oxide layer 42 is suppressed, with the result that the resistance of the oxide semiconductor layer 4 is prevented from lowering and favorable switching characteristics can be obtained.

The embodiment of the present invention has been described heretofore. However, the present invention is not limited to the embodiment above and can be variously modified without departing from the gist of the present invention.

For example, in the embodiment above, regarding the first metal oxide layer 41 and the second metal oxide layer 42 constituting the oxide semiconductor layer 4, the second metal oxide layer 42 is formed of a metal oxide layer having higher resistance than the first metal oxide layer 41. However, the first metal oxide layer 41 may be formed of a metal oxide layer having higher resistance than the second metal oxide layer 42.

In the embodiment above, the lower electrode layer 3 is formed of TiN, but DLC may be used instead. In this case, it becomes difficult for the lower electrode layer 3 to transmit and absorb oxygen in the oxide semiconductor layer 4, and thus the resistance of the element can be prevented from lowering.

In the embodiment above, the entire upper electrode layer 5 is formed of a carbon material. However, only the interface of the upper electrode layer 5 with the second metal oxide layer 42 may be formed of the carbon material. Also with this structure, operational effects similar to those of the embodiment above can be obtained. In this case, for example, the upper electrode layer 5 can be constituted of a thin film formed of a carbon material and an electrode layer formed on the thin film, and an arbitrary electrode material can be used for the electrode layer.

### DESCRIPTION OF REFERENCE NUMERALS

1 variable-resistance element
2 substrate
3 lower electrode layer (first electrode layer)
4 oxide semiconductor layer
5 upper electrode layer (second electrode layer)
41 first metal oxide layer
42 second metal oxide layer

1. A variable-resistance element, comprising:
a first electrode layer;
a second electrode layer formed of a carbon material; and
an oxide semiconductor layer including
a first metal oxide layer that is formed between the first electrode layer and the second electrode layer and includes a first resistivity, and
a second metal oxide layer that is formed between the first metal oxide layer and the second electrode layer and includes a second resistivity different from the first resistivity.

2. The variable-resistance element according to claim 1,
wherein the carbon material is diamond-like carbon.

3. The variable-resistance element according to claim 2,
wherein a density value of the diamond-like carbon is within a range of 2.3 g/cm³ or more and 2.6 g/cm³ or less.

4. A method of producing a variable-resistance element, comprising:
forming a first electrode layer on a substrate;
forming a first metal oxide layer including a first resistivity on the first electrode layer;
forming a second metal oxide layer including a second resistivity different from the first resistivity on the first metal oxide layer; and
forming a second electrode layer formed of diamond-like carbon on the second metal oxide layer by RF sputtering or pulse DC sputtering.
